(19) United States
(12) Patent Application Publication
(10) Pub. No.: US 2026/0299416 A1
(43) Pub. Date: Oct. 1, 2026

(54) PHOTOSENSITIVE RESIN COMPOSITION, PHOTOSENSITIVE ELEMENT, METHOD FOR FORMING RESIST PATTERN, AND METHOD FOR MANUFACTURING WIRING SUBSTRATE

(71) Applicant: Resonac Corporation, Tokyo (JP)

(72) Inventors: Yusuke SAKASHITA, Tokyo (JP); Akane ONO, Tokyo (JP); Keishi ONO, Tokyo (JP); Mao NARITA, Tokyo (JP)

(73) Assignee: Resonac Corporation, Tokyo (JP)

(21) Appl. No.: 19/478,956

(22) PCT Filed: Sep. 11, 2024
(86) PCT No.: PCT/JP2024/032544

§ 371 Date: Oct. 27, 2025

(30) Foreign Application Priority Data
Sep. 29, 2023 (JP) 2023-169437

(51) Int. Cl. G03F 7/033; G03F 7/004; G03F 7/42; H05K 3/06; H05K 3/18; H05K 3/26

(52) U.S. Cl. CPC G03F 7/033; G03F 7/0045; G03F 7/42; H05K 3/064; H05K 3/184; H05K 3/26; H05K 2203/072

(57) ABSTRACT

A photosensitive resin composition according to the present disclosure includes: a binder polymer; a photopolymerizable compound; a photopolymerization initiator; and a sensitizer, in which the photopolymerizable compound includes a monofunctional (meth)acrylate having a bicyclo skeleton, and the content of the monofunctional (meth)acrylate having a bicyclo skeleton is less than 5.0 parts by mass with respect to 100 parts by mass of the total amount of the binder polymer and the photopolymerizable compound.

### TECHNICAL FIELD

The present disclosure relates to a photosensitive resin composition, a photosensitive element, a method of forming a resist pattern, and a method of manufacturing a wiring substrate.

### BACKGROUND ART

In the field of manufacturing wiring substrates, photosensitive resin compositions and photosensitive elements including layers (hereinafter, also referred to as “photosensitive layers”) formed on supports using photosensitive resin compositions have widely been used as resist materials to be used in the etching process or plating process.

A wiring substrate is manufactured, for example, by the following procedure. First, a photosensitive layer of a photosensitive element is laminated on a circuit formation substrate (photosensitive layer formation process). Next, predetermined portions of the photosensitive layer are exposed to light to form photocured portions (exposure process). At this time, the support is peeled off before or after the exposure. Thereafter, a region of the photosensitive layer other than the photocured portions is removed from the substrate, and a resist pattern which is a cured product of a photosensitive resin composition is formed on the substrate (developing process). Next, etching process or plating process is applied using the obtained resist pattern as a resist to form a conductor pattern on the substrate (circuit formation process), and the resist is finally peeled off and removed (peeling-off process).

As an exposure method, a method of performing exposure through a photomask using a mercury lamp as a light source is known in the related art. In recent years, a direct drawing exposure method called laser direct imaging (LDI), in which digital data of a pattern is drawn directly on a photosensitive layer, has been used as an exposure method that does not require a photomask. The direct drawing exposure method is being introduced for producing high-density package substrates because the direct drawing exposure method exhibits a higher alignment accuracy than an exposure method through a photomask and can obtain a highly precise pattern.

In general, it is desired to shorten an exposure time in the exposure process in order to improve production efficiency. However, the above-described direct drawing exposure method uses monochromatic light such as a laser as a light source, also includes performing irradiation with active rays while scanning a substrate, and thus tends to require a longer exposure time as compared with the exposure method through a photomask in the related art. Therefore, in order to shorten the exposure time and increase production efficiency, it is necessary to further improve sensitivity of the photosensitive resin composition.

In the peeling-off process, it is desired to shorten the resist peeling-off time in order to improve production efficiency. Therefore, a photosensitive resin composition having excellent releasability after curing has been required. Moreover, a photosensitive resin composition capable of forming resist patterns with excellent resolution and adhesion has also been required with an increase in density of wiring substrates in recent years.

In response to these demands, various photosensitive resin compositions have been studied in the related art. For example, PTL 1 discloses a photosensitive resin composition having excellent sensitivity and resolution by using a specific photosensitizer. PTL 2 discloses a photosensitive resin composition having excellent sensitivity and resolution by using a specific alkali-soluble polymer and a compound having an ethylenic double bond.

### CITATION LIST

### Patent Literature

[PTL 1] Japanese Patent Application Publication No. 2009-003177
[PTL 2] Japanese Patent Application Publication No. 2013-061556

### SUMMARY OF INVENTION

### Technical Problem

In recent years, photosensitive resin compositions have been required to form resist patterns, such as via hole patterns, with high resolution in order to form copper pillars for connecting IC chips and semiconductor package wiring substrates, for example. However, since it is more difficult to uniformly cure photosensitive layers formed by using photosensitive resin compositions up to their bottom portions as the thicknesses increase, it is difficult to form resist patterns having sufficient resolution and adhesion. Furthermore, resist patterns having excellent adhesion tend to lead to long peeling-off times. Therefore, the photosensitive resin compositions are required to form resist patterns having excellent adhesion and resolution and have excellent releasability after curing.

An object of the present disclosure is to provide a photosensitive resin composition having excellent resolution, adhesion, and releasability, a photosensitive element using the photosensitive resin composition, a method of forming a resist pattern, and a method of manufacturing a wiring substrate.

### Solution to Problem

The present disclosure provides the following photosensitive resin composition, photosensitive element, method of forming a resist pattern, and method of manufacturing a wiring substrate.
[1]A photosensitive resin composition including: a binder polymer; a photopolymerizable compound; a photopolymerization initiator; and a sensitizer, in which the photopolymerizable compound includes monofunctional (meth)acrylate having a bicyclo skeleton, and a content of the monofunctional (meth)acrylate having a bicyclo skeleton is less than 5.0 parts by mass with respect to 100 parts by mass of a total amount of the binder polymer and the photopolymerizable compound.
[2] The photosensitive resin composition according to [1] above, in which the content of the monofunctional (meth)acrylate having a bicyclo skeleton is 1.0 parts by mass to 4.5 parts by mass with respect to 100 parts by mass of the total amount of the binder polymer and the photopolymerizable compound.
[3] The photosensitive resin composition according to [1] or [2] above, in which the photopolymerizable compound further includes bisphenol A type (meth)acrylate.
[4] The photosensitive resin composition according to any one of [1] to [3] above, in which the sensitizer includes an anthracene compound.
[5]A photosensitive element including: a support; and a photosensitive layer formed on the support using the photosensitive resin composition according to any one of [1] to [4] above.
[6] The photosensitive element according to [5] above, in which a thickness of the photosensitive layer is equal to or greater than 30 μm.
[7]A method of forming a resist pattern, including: forming a photosensitive layer on a substrate using the photosensitive element according to [6] above; irradiating at least a part of the photosensitive layer with active rays to form a photocured portion; and removing an unphotocured portion of the photosensitive layer from the substrate to form a resist pattern.
[8]A method of manufacturing a wiring substrate, including: performing etching process or plating process on a substrate with a resist pattern formed thereon by the method of forming a resist pattern according to [7] above to form a conductor pattern.
[9] The method of manufacturing a wiring substrate according to [8] above, further including: removing the resist pattern using an organic alkali stripper after the etching process or the plating process.

### Advantageous Effects of Invention

According to the present disclosure, it is possible to provide a photosensitive resin composition having excellent resolution, adhesion, and releasability, a photosensitive element using the photosensitive resin composition, a method of forming a resist pattern, and a method of manufacturing a wiring substrate.

### BRIEF DESCRIPTION OF DRAWINGS

FIG. 1 is a schematic sectional view illustrating an embodiment of a photosensitive element.

### DESCRIPTION OF EMBODIMENTS

Hereinafter, an embodiment of the present disclosure will be described in detail. In the present specification, the term “process” includes not only an independent process but also a process that cannot be clearly distinguished from other processes as long as a prescribed effect of the process is achieved. The term “layer” includes not only a structure with a shape formed on an entire surface but also a structure with a shape formed on a part of the surface in observation in a plan view. Numerical ranges indicated using “to” indicate ranges including the numerical values stated before and after “to” as the minimum and maximum values, respectively. In numerical ranges stated in stages in the present specification, an upper limit value or a lower limit value of a numerical range in a certain stage may be replaced with an upper limit value or a lower limit value of a numerical range in another stage. In a numerical range described in the present specification, an upper limit value or a lower limit value of the numerical range may be replaced with values indicated in the Examples.

As used in the present specification, “(meth)acrylate” means at least either “acrylate” or “methacrylate” corresponding thereto. The same applies to other similar expressions such as “(meth)acryloyl”. “EO” indicates ethylene oxide, and an “EO-modified” compound means a compound having an oxyethylene group. “PO” indicates propylene oxide, and a “PO-modified” compound means a compound having an oxypropylene group.

In the present specification, in a case where a plurality of substances corresponding to each component are present in a composition, the amount of each component in a photosensitive resin composition means the total amount of the plurality of substances that are present in the composition unless otherwise particularly specified. In the present specification, the term “solid content” refers to a nonvolatile content from which substances that volatilize (water, a solvent, and the like) are excluded in the photosensitive resin composition. In other words, “solid content” refers to components, which remain without volatilization after drying of the photosensitive resin composition described later, other than the solvent and also includes components in a liquid form, a starch syrupy-like form, or a wax form at a room temperature (25° C.).

### [Photosensitive Resin Composition]

The photosensitive resin composition according to the present embodiment contains (A) a binder polymer (hereinafter, referred to as a “component (A)” in some cases), (B) a photopolymerizable compound (hereinafter, referred to as a “component (B)” in some cases), (C) a photopolymerization initiator (hereinafter, referred to as a “component (C)” in some cases), and (D) a sensitizer (hereinafter, referred to as a “component (D)” in some cases). The photopolymerizable compound includes a monofunctional (meth)acrylate having a bicyclo skeleton, and the content of the monofunctional (meth)acrylate having a bicyclo skeleton in the photosensitive resin composition is less than 5.0 parts by mass with respect to 100 parts by mass of the total amount of the binder polymer and the photopolymerizable compound. The photosensitive resin composition according to the present embodiment has excellent resolution, adhesion, and releasability and can be suitably used for applications of thick films due to containing such a specific photopolymerizable compound within the specific range. Each component will be described below.

### (Component (A): Binder Polymer)

The photosensitive resin composition includes one or more kinds of components (A). Examples of the components (A) include an acrylic resin, a styrene-based resin, an epoxy-based resin, an amide-based resin, an amide epoxy-based resin, an alkyd-based resin, and a phenol-based resin.

The component (A) may include an acrylic resin from the viewpoint of alkali developability. The acrylic resin is a resin having a structural unit (monomer unit) derived from a (meth)acryloyl group-containing compound.

The (meth)acryloyl group-containing compound is a compound that contains a (meth)acryloyl group. Examples of the (meth)acryloyl group-containing compound include hydroxyalkyl (meth)acrylate, (meth)acrylic acid, (meth)acrylic acid alkyl ester, (meth)acrylic acid aryl ester, (meth)acrylic acid cycloalkyl ester, acryl amide such as diacetonacrylamide, (meth)acrylic acid tetrahydrofuryl ester, (meth)acrylic acid dimethylaminoethyl ester, (meth)acrylic acid diethylaminoethyl ester, (meth)acrylic acid glycidyl ester, 2,2,2-trifluoroethyl (meth)acrylate, 2,2,3,3-tetrafluoropropyl(meth)acrylate, α-bromoacrylic acid, α-chloracrylic acid, β-furyl(meth)acrylic acid, and β-styryl(meth)acrylic acid.

Examples of the acrylic resin may be a polymer (a) including at least one kind selected from the group consisting of a (meth)acrylic acid unit, a (meth)acrylic acid alkyl ester unit, a (meth)acrylic acid aryl ester unit, and a hydroxyalkyl (meth)acrylate unit.

The (meth)acrylic acid unit is a structural unit derived from (meth)acrylic acid. In a case where the polymer (a) includes a (meth)acrylic acid unit, the content of the (meth)acrylic acid unit may be equal to or greater than 5% by mass, equal to or greater than 10% by mass, equal to or greater than 15% by mass, equal to or greater than 20% by mass, or equal to or greater than 25% by mass and may be equal to or less than 50% by mass, equal to or less than 45% by mass, equal to or less than 40% by mass, equal to or less than 35% by mass, or equal to or less than 30% by mass from the viewpoint of resolution and adhesion with respect to the total amount (100% by mass) of the monomer units constituting the polymer (a).

The (meth)acrylic acid alkyl ester unit is a structural unit derived from (meth)acrylic acid alkyl ester. An alkyl group of the (meth)acrylic acid alkyl ester may be, for example, a methyl group, an ethyl group, a propyl group, a butyl group, a pentyl group, a hexyl group, a heptyl group, an octyl group, a nonyl group, a decyl group, an undecyl group, a dodecyl group, or a structural isomer thereof, and the alkyl group may be an alkyl group having 1 to 4 carbon atoms from the viewpoint of releasability.

In a case where the polymer (a) includes the (meth)acrylic acid alkyl ester unit, the content of the (meth)acrylic acid alkyl ester unit may be equal to or greater than 1% by mass, equal to or greater than 2, by mass, or equal to or greater than 3% by mass from the viewpoint of releasability and may be equal to or less than 30by mass, equal to or less than 20, by mass, equal to or less than 10% by mass, or equal to or less than 8% by mass from the viewpoint of resolution and adhesion, with respect to the total amount of the monomer units constituting the polymer (a).

The (meth)acrylic acid aryl ester unit is a structural unit derived from a (meth)acrylic acid aryl ester. Examples of (meth)acrylic acid aryl ester include benzyl (meth)acrylate, phenyl (meth)acrylate, and naphthyl (meth)acrylate. In a case where the polymer (a) includes the (meth)acrylic acid aryl ester unit, the content of the (meth)acrylic acid aryl ester unit may be equal to or greater than 5 by mass, equal to or greater than 10 by mass, equal to or greater than 15% by mass, or equal to or greater than 20% by mass and may be equal to or less than 40% by mass, equal to or less than 35% by mass, equal to or less than 30% by mass, or equal to or less than 25% by mass with respect to the total amount of monomer units constituting the polymer (a) from the viewpoint of resolution and adhesion.

The hydroxyalkyl (meth)acrylate unit is a structural unit derived from hydroxyalkyl (meth)acrylate. Examples of hydroxyalkyl (meth)acrylate include hydroxymethyl (meth)acrylate, hydroxyethyl (meth)acrylate, hydroxypropyl (meth)acrylate, hydroxybutyl (meth)acrylate, hydroxypentyl (meth)acrylate, and hydroxyhexyl (meth)acrylate. In a case where the number of carbon atoms in the alkyl part in the hydroxyalkyl (meth)acrylate unit is equal to or greater than three, a branched structure may be included.

In a case where the polymer (a) includes the hydroxyalkyl (meth)acrylate unit, the content of the hydroxyalkyl (meth)acrylate unit may be equal to or greater than 0.5 by mass, equal to or greater than 0.75% by mass, or equal to or greater than 1.0% by mass from the viewpoint of dispersibility and may be equal to or less than 20′ by mass, equal to or less than 15% by mass, or equal to or less than 8 by mass from the viewpoint of water absorption, with respect to the total amount of the monomer units constituting the polymer (a).

The polymer (a) may have a structural unit (hereinafter, also referred to as a “styrene-based unit”) derived from styrene or a styrene derivative in order to further improve resolution and adhesion of the photosensitive resin composition. Examples of the styrene derivative include vinyltoluene, α-methylstyrene, p-methylstyrene, and p-ethylstyrene.

In a case where the polymer (a) includes the styrenic unit, the content of the styrenic unit may be equal to or greater than 35% by mass, equal to or greater than 40% by mass, equal to or greater than 43% by mass, or equal to or greater than 45% by mass from the viewpoint of resolution and may be equal to or less than 70% by mass, equal to or less than 60% by mass, equal to or less than 50% by mass, or equal to or less than 48% by mass from the viewpoint of developability, with respect to the total amount of the monomer units constituting the polymer (a).

The polymer (a) may further include structural units derived from monomers other than those described above. Examples of other monomers include ethers of vinyl alcohol such as acrylonitrile and vinyl-n-butyl ether, maleic acid, maleic anhydride, a maleic acid monoester such as monomethyl maleate, monoethyl maleate, and monoisopropyl maleate, fumaric acid, cinnamic acid, α-cyanocinnamic acid, itaconic acid, crotonic acid, and propiolic acid.

The component (A) may include a binder polymer other than the polymer (a) or may include only the polymer (a). The content of the polymer (a) in the component (A) may be 50% by mass to 100% by mass or 80% by mass to 100% by mass with respect to the total amount of the component (A) from the viewpoint of adhesion and resolution.

The acid value of the polymer (a) may be equal to or greater than 100 mg KOH/g, equal to or greater than 120 mg KOH/g, equal to or greater than 140 mgKOH/g, equal to or greater than 150 mgKOH/g, equal to or greater than 160 mgKOH/g, or equal to or greater than 170 mgKOH/g from the viewpoint of developability and may be equal to or less than 250 mgKOH/g, equal to or less than 240 mgKOH/g, equal to or less than 230 mgKOH/g, equal to or less than 200 mgKOH/g, or equal to or less than 190 mgKOH/g from the viewpoint of adhesion (developer resistance) of the cured product of the photosensitive resin composition. The acid value of the polymer (a) can be adjusted by the content of the structural units (for example, the (meth)acrylic acid unit) constituting the polymer (a). In a case where the component (A) includes a binder polymer other than the polymer (a), the acid value of the other binder polymer may also fall within the above range.

The weight average molecular weight (Mw) of the polymer (a) may be equal to or greater than 10000, equal to or greater than 20000, equal to or greater than 25000, equal to or greater than 30000, equal to or greater than 35000, equal to or greater than 40000, or equal to or greater than 45000 from the viewpoint of adhesion (developer resistance) of the cured product of the photosensitive resin composition and easiness of formation of a resist pattern in a thick film and may be equal to or less than 100000, equal to or less than 80000, equal to or less than 60000, or equal to or less than 50000 from the viewpoint of developability. The dispersity (Mw/Mn) of the polymer (a) may be equal to or greater than 1.0 or equal to or greater than 1.5, for example, and may be equal to or less than 3.0 or equal to or less than 2.5 from the viewpoint of adhesion and resolution. In a case where the component (A) includes a binder polymer other than the polymer (a), Mw of the other binder polymer may also fall within the above range.

The weight-average molecular weight and the dispersity can be measured using a standard polystyrene calibration curve by gel permeation chromatography (GPC), for example. More specifically, the weight-average molecular weight and the dispersity can be measured under the conditions described in the Examples. Note that in a case where it is difficult to measure the weight-average molecular weight of a compound with a small molecular weight by the above-described method of measuring the molecular weight, it is also possible to measure molecular weights by other methods and to calculate an average thereof.

The content of the component (A) may be equal to or greater than 20% by mass, equal to or greater than 30% by mass, or equal to or greater than 40% by mass from the viewpoint of film moldability and may be equal to or less than 90% by mass, equal to or less than 80% by mass, equal to or less than 70% by mass, or equal to or less than 65% by mass from the viewpoint of sensitivity and resolution, with respect to the total amount of the solid content in the photosensitive resin composition.

The content of the component (A) may be equal to or greater than 30 parts by mass, equal to or greater than 40 parts by mass, or equal to or greater than 50 parts by mass from the viewpoint of film moldability and may be equal to or less than 70 parts by mass, equal to or less than 65 parts by mass, or equal to or less than 60 parts by mass from the viewpoint of sensitivity and resolution, with respect to 100 parts by mass of the total amount of the component (A) and the component (B).

### (Component (B): Photopolymerizable Compound)

The photosensitive resin composition includes, as the component (B), a monofunctional (meth)acrylate having a bicyclo skeleton (hereinafter, also referred to as a “component (b1)”) from the viewpoint of releasability, and the content of the component (b1) is less than 5.0 parts by mass with respect to 100 parts by mass of the total amount of the component (A) and the component (B) from the viewpoint of adhesion and resolution.

Examples of the component (b1) include dicyclopentanyl (meth)acrylate, isobornyl (meth)acrylate, and adamantyl (meth)acrylate.

The content of the component (b1) may be 1.0 parts by mass to 4.5 parts by mass, 1.5 parts by mass to 4.0 parts by mass, 2.0 parts by mass to 3.5 parts by mass, or 2.5 parts by mass to 3.3 parts by mass with respect to 100 parts by mass of the total amount of the component (A) and the component (B) from the viewpoint of satisfying all of adhesion, resolution, and releasability.

The component (B) may include difunctional (meth)acrylate (hereinafter, also referred to as a “component (b2)”), which is a compound having two (meth)acryloyl groups from the viewpoint of developability, resolution, and releasability. Examples of the component (b2) include bisphenol A type (meth)acrylate such as 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl)propane; polyalkylene glycol di(meth)acrylates such as polyethylene glycol di(meth)acrylate, polypropylene glycol di(meth)acrylate, and EO-modified polypropylene glycol di(meth)acrylate; and di(meth)acrylate having an alicyclic skeleton such as cyclohexyl di(meth)acrylate and tricyclodecanedimethanol di(meth)acrylate.

The component (b2) is preferably bisphenol A type (meth)acrylate and is more preferably 2,2-bis(4-(meth)acryloxypolyethoxy)phenyl)propane from the viewpoint of further improving resolution and releasability.

The content of the component (b2) may be equal to or greater than 20 parts by mass, equal to or greater than 25 parts by mass, equal to or greater than 30 parts by mass, or equal to or greater than 35 parts by mass and may be equal to or less than 65 parts by mass, equal to or less than 60 parts by mass, equal to or less than 50 parts by mass, or equal to or less than 45 parts by mass with respect to 100 parts by mass of the total amount of the component (A) and the component (B) from the viewpoint of further improving resolution and adhesion. In other words, the content of the component (b2) may be 20 parts by mass to 65 parts by mass, 25 parts by mass to 60 parts by mass, 30 parts by mass to 50 parts by mass, or 35 parts by mass to 45 parts by mass with respect to 100 parts by mass of the total amount of the component (A) and the component (B).

The component (B) may further include a compound (hereinafter, also referred to as a component “(b3)”) having three or more (meth)acryloyl groups from the viewpoint of sensitivity, developability, and adhesion. Examples of the component (b3) include trimethylolpropane tri(meth)acrylate, EO-modified trimethylolpropane tri(meth)acrylate, PO-modified trimethylolpropane tri(meth)acrylate, EO/PO-modified trimethylolpropane tri(meth)acrylate, EO-modified pentaerythritol tetra(meth)acrylate, EO-modified ditrimethylolpropane tetra(meth)acrylate, EO-modified dipentaerythritol hexa(meth)acrylate, tetramethylolmethane tri(meth)acrylate, and tetramethylolmethane tetra(meth)acrylate.

The content of the component (b3) may be equal to or greater than 1% by mass, equal to or greater than 5% by mass, or equal to or greater than 10% by mass and may be equal to or less than 25% by mass, equal to or less than 20% by mass, or equal to or less than 15% by mass with respect to the total amount of the component (B).

The photosensitive resin composition may further include photopolymerizable compounds other than the components (b1), (b2), and (b3) described above as the components (B).

Examples of other photopolymerizable compounds include a urethane monomer, nonylphenoxy polyethylenoxy (meth)acrylate, a phthalic acid compound, a (meth)acrylic acid alkyl ester, and a photopolymerizable compound (such as an oxetane compound) having at least one cationic polymerizable cyclic ether group in a molecule. Other photopolymerizable compounds may be at least one kind selected from a group consisting of a urethane monomer, nonylphenoxy polyethyleneoxy (meth)acrylate, and a phthalic acid compound from the viewpoint of resolution, adhesion, a resist shape, and releasability.

Examples of nonylphenoxypolyethylenoxy (meth)acrylate include nonylphenoxytriethylenoxy (meth)acrylate, nonylphenoxytetraethylenoxy (meth)acrylate, nonylphenoxypentaethylenoxy (meth)acrylate, nonylphenoxyhexaethylenoxy (meth)acrylate, nonylphenoxyheptaethylenoxy (meth)acrylate, nonylphenoxyoctaethylenoxy (meth)acrylate, nonylphenoxynonaethylenoxy (meth)acrylate, nonylphenoxydecaethylenoxy (meth)acrylate, and nonylphenoxyundecaethylenoxy (meth)acrylate.

Examples of the phthalic acid-based compound include γ-chloro-β-hydroxypropyl-β′-(meth)acryloyloxyethyl-o-phthalate (also known as 3-chloro-2-hydroxypropyl-2-(meth)acryloyloxyethyl phthalate), β-hydroxyethyl-β′-(meth)acryloyloxyethyl-o-phthalate, and β-hydroxypropyl-β′-(meth)acryloyloxyethyl-o-phthalate.

The content of the component (B) may be equal to or greater than 3% by mass, equal to or greater than 10% by mass, or equal to or greater than 25% by mass from the viewpoint of sensitivity and resolution and may be equal to or less than 70% by mass, equal to or less than 60% by mass, or equal to or less than 50% by mass from the viewpoint of film moldability, with respect to the total amount of the solid content in the photosensitive resin composition.

### (Component (C): Photopolymerization Initiator)

The photosensitive resin composition includes one or more kinds of components (C). The component (C) is not particularly limited as long as the component can polymerize the component (B), and the component (C) can be appropriately selected from typically used photopolymerization initiators.

Examples of the component (C) include: hexaarylbiimidazole compounds; aromatic ketone compounds such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 4-(2-hydroxyethoxy)phenyl-2-(hydroxy-2-propyl)ketone, and 2-methyl-1-[4-(methylthio)phenyl]-2-morpholino-propanone-1; quinone compounds such as alkylanthraquinone; benzoin ether compounds such as benzoin alkyl ether; benzoin compounds such as benzoin and alkylbenzoin; benzyl derivatives such as benzyldimethyl ketal; and phosphine oxide compounds such as bis(2,4,6-trimethylbenzoyl)-phenylphosphine oxide, bis(2,6-dimethylbenzoyl)-2,4,4-trimethyl-pentylphosphine oxide, and (2,4,6-trimethylbenzoyl)ethoxyphenylphosphine oxide.

The component (C) may include a hexaarylbiimidazole compound from the viewpoint of improving adhesion of the photosensitive layer with respect to a smooth substrate. An aryl group in the hexaarylbiimidazole compound may be a phenyl group or the like. The hydrogen atom bonded to the aryl group in the hexaarylbiimidazole compound may be substituted with a halogen atom (such as a chlorine atom).

The hexaarylbiimidazole compound may be a 2,4,5-triarylimidazole dimer. Examples of the 2,4,5-triarylimidazole dimer include a 2-(o-chlorophenyl)-4,5-diphenylimidazole dimer, a 2-(o-chlorophenyl)-4,5-bis-(m-methoxyphenyl)imidazole dimer, and a 2-(p-methoxyphenyl)-4,5-diphenylimidazole dimer.

The content of component (C) may be 1.0 parts by mass to 10 parts by mass, 2.0 parts by mass to 8 parts by mass, 3.0 parts by mass to 7.0 parts by mass, or 4.0 parts by mass to 6.0 parts by mass with respect to 100 parts by mass of the total amount of the component (A) and the component (B). It is easier to improve both photosensitivity and resolution with a satisfactory balance when the content of the component (C) falls within the range.

### (Component (D): Sensitizer)

The photosensitive resin composition according to the present embodiment can effectively utilize an absorption wavelength of active rays used for exposure by containing the component (D).

Examples of the component (D) include a dialkylaminobenzophenone compound, a pyrazoline compound, an anthracene compound, a coumarin compound, a xanthone compound, a thioxanthone compound, an oxazole compound, a benzoxazole compound, a thiazole compound, a benzothiazole compound, a triazole compound, a stilbene compound, a triazine compounds, a thiophene compound, a naphthalimide compound, a triarylamine compound, and an aminoacridine compound. The component (D) may include an anthracene compound from the viewpoint of further improving resolution and adhesion.

Examples of the anthracene compound include 9,10-dibutoxyanthracene, 9,10-diphenylanthracene, and 9,10-diethoxyanthracene. From the viewpoint of sensitivity, adhesion, resolution, and releasability, the anthracene compound may include 9,10-dibutoxyanthracene.

The content of the component (D) may be equal to or greater than 0.2 parts by mass, equal to or greater than 0.3 parts by mass, equal to or greater than 0.4 parts by mass, or equal to or greater than 0.5 parts by mass and may be equal to or less than 1.5 parts by mass, equal to or less than 1.0 parts by mass, equal to or less than 0.8 parts by mass, equal to or less than 0.75 parts by mass, or equal to or less than 0.7 parts by mass with respect to 100 parts by mass of the total amount of the component (A) and the component (B) from the viewpoint of improving sensitivity and resolution.

### (Other Components)

The photosensitive resin composition may further contain one or more kinds of components other than the components described above. Examples of other components include a polymerization inhibitor, a hydrogen donor (such as bis[4-(dimethylamino)phenyl]methane, bis[4-(diethylamino)phenyl]methane, leuco crystal violet, N-phenylglycine, or the like), a dye (such as malachite green), tribromophenyl sulfone, a photochromic agent, a heat color stabilizer, a plasticizer (such as p-toluenesulfonamide), a pigment, a filler, a defoaming agent, a flame retardant, a stabilizer, an adhesion-imparting agent, a leveling agent, a stripping accelerator, an antioxidant, a fragrance, an imaging agent, and a thermal crosslinker. The content of other components may be equal to or greater than 0.005 parts by mass or equal to or greater than 0.01 parts by mass and may be equal to or less than 20 parts by mass with respect to 100 parts by mass of the total amount of the component (A) and the component (B).

The photosensitive resin composition can contain an organic solvent in order to improve a handling property of the photosensitive composition or to adjust viscosity and storage stability. As the organic solvent, any typically used organic solvent can be used without any particular limitation. Examples of the organic solvent include methanol, ethanol, acetone, methyl ethyl ketone, methyl cellosolve, ethyl cellosolve, toluene, N,N-dimethylformamide and propylene glycol monomethyl ether. For example, the components (A) to (D) can be dissolved in the organic solvent and can be used as a solution having a solid content of about 30% by mass to 60% by mass.

The photosensitive resin composition according to the present embodiment may be in the liquid form or in the film (photosensitive film) form. The photosensitive resin composition can be used, for example, as a negative-type photosensitive resin composition. The photosensitive resin composition can be suitably used in a method of forming a resist pattern and a method of manufacturing a wiring substrate, which will be described later.

### [Photosensitive Element]

A photosensitive element of the present embodiment includes a support and a photosensitive layer formed on the support, and the photosensitive layer includes the photosensitive resin composition described above. The content of each component other than volatilizing substances (the components (A) to (D) and other components) in the photosensitive layer may be within the numerical range of the content of each component in the photosensitive resin composition described above. In a case where the photosensitive element according to the present embodiment is used, exposure may be performed without peeling off the support (support film) after the photosensitive layer is laminated on a substrate.

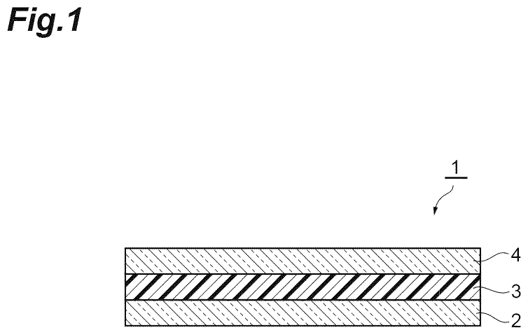

FIG. 1 is a schematic sectional view of a photosensitive element according to an embodiment. As illustrated in FIG. 1, a photosensitive element 1 includes a support 2 and a photosensitive layer 3 derived from the above-described photosensitive resin composition formed on the support 2 and is configured to include a protective layer 4 and the like and other layers provided as needed.

Each of the support 2 and the protective layer 4 may be a polymer film having heat resistance and solvent resistance, and examples thereof may include polyester films such as a polyethylene terephthalate film and polyolefin films such as a polyethylene film and a polypropylene film. Each of the support 2 and the protective layer 4 may be a film of a hydrocarbon-based polymer other than polyolefin. A film of a hydrocarbon-based polymer containing polyolefin may have a low density, for example, a density of equal to or less than 1.014 g/cm³. Each of the support 2 and the protective layer 4 may be a stretched film obtained by stretching the low-density hydrocarbon-based polymer film. The kind of polymer film constituting the protective layer 4 may be the same as or different from the kind of polymer film constituting the support 2.

Each of these polymer films can be purchased as a polyethylene terephthalate film of PS series (for example, PS-25) manufactured by Teijin Limited., a polyethylene film of NF-15 or the like manufactured by Tamapoly Co., Ltd., or a polypropylene film (for example, Alphan MA-410 or E-200C) manufactured by Oji Paper Co., Ltd. or manufactured by Shin-Etsu Film Co., Ltd., for example.

The thickness of the support 2 may be equal to or greater than 1 μm or equal to or greater than 5 μm from the viewpoint that breakage of the support 2 can be reduced when the support 2 is peeled off from the photosensitive layer 3 and may be equal to or less than 100 μm, equal to or less than 50 μm, or equal to or less than 30 μm from the viewpoint that it is possible to suitably perform exposure even in a case where the exposure is performed via the support 2.

The thickness of the protective layer 4 may be equal to or greater than 1 μm, equal to or greater than 5 μm, or equal to or greater than 15 μm from the viewpoint that breakage of the protective layer 4 can be reduced when the photosensitive layer 3 and the support 2 are laminated on the substrate while the protective layer 4 is peeled off and may be equal to or less than 100 μm, equal to or less than 50 μm, or equal to or less than 30 μm from the viewpoint that productivity is improved.

The photosensitive layer 3 is made of the above-described photosensitive resin composition. The thickness of the photosensitive layer 3 after drying (after an organic solvent is caused to volatilize in a case where the photosensitive resin composition contains the organic solvent) may be 30 μm to 100 μm. The thickness of the photosensitive layer may be equal to or greater than 30 μm, equal to or greater than 35 μm, equal to or greater than 38 μm, equal to or greater than 40 μm, or equal to or greater than 50 μm from the viewpoint of forming a resist pattern with a high aspect ratio and may be equal to or less than 100 μm, equal to or less than 90 μm, equal to or less than 80 μm, equal to or less than 70 μm, or equal to or less than 60 μm from the viewpoint of releasability.

The photosensitive element 1 can be obtained as follows, for example. First, the photosensitive layer 3 is formed on the support 2. The photosensitive layer 3 can be formed by, for example, applying the photosensitive resin composition containing the organic solvent to form a coating layer and drying the coating layer. Then, a protective layer 4 is formed on the surface of the photosensitive layer 3 on the side opposite to the support 2.

The coating layer is formed by a known method such as roll coating, comma coating, gravure coating, air knife coating, die coating, or bar coating, for example. The drying of the coating layer is performed such that the amount of organic solvent remaining in the photosensitive layer 3 becomes equal to or less than 2% by mass, for example, and specifically, the drying is performed at 70° C. to 150° C. for 5 minutes to 30 minutes, for example.

The photosensitive element may further include an intermediate layer between the support 2 and the photosensitive layer 3. The intermediate layer may be a layer containing a water-soluble resin. Examples of the water-soluble resin include a resin including polyvinyl alcohol as a main component.

The photosensitive element may not include a protective layer and may include other layers such as a cushion layer, an adhesive layer, a light absorbing layer, and a gas barrier layer in another embodiment.

The photosensitive element 1 may be in the sheet form or in a form of a photosensitive element roll wound around a winding core in a roll shape, for example. In the photosensitive element roll, the photosensitive element 1 is preferably wound such that the support 2 is located outside. The winding core is formed of, for example, polyethylene, polypropylene, polystyrene, polyvinyl chloride, or an acrylonitrile-butadiene-styrene copolymer. An end surface of the photosensitive element roll may be provided with an end surface separator from the viewpoint of protecting the end surface or may be provided with a moisture-proofing end surface separator from the viewpoint of edge fusion resistance. The photosensitive element 1 may be wrapped by, for example, a black sheet having low moisture permeability.

The photosensitive element 1 can be suitably used for forming a resist pattern and can be particularly suitably used in a method of manufacturing a print wiring substrate, which will be described later.

### [Method of Forming Resist Pattern]

A method of forming a resist pattern of the present embodiment may be configured to include: a process of forming a photosensitive layer on a substrate using the above-described photosensitive resin composition or the above-described photosensitive element (photosensitive layer formation process); a process of irradiating at least a part (predetermined part) of the photosensitive layer with active rays to form a photocured portion (exposure process); and a process of removing at least a part of the above-described unphotocured portion from the substrate (developing process), and the method may further include other processes as needed. The resist pattern may be referred to as a photocured product pattern of the photosensitive resin composition or may be referred to as a relief pattern. The method of forming the resist pattern may also be referred to as a method of manufacturing a resist patterned substrate.

### (Photosensitive Layer Formation Process)

As a method of forming the photosensitive layer on the substrate, the photosensitive resin composition may be applied and dried, or the photosensitive layer of the photosensitive element may be pressure-bonded to the substrate while being heated after the protective layer is removed from the photosensitive element. In a case where the photosensitive element is used, a laminate including a substrate, a photosensitive layer, and a support stacked in this order is obtained. Although the substrate is not particularly limited, a circuit formation substrate including an insulating layer and a conductor layer formed on the insulating layer or a die pad (lead frame base material) such as an alloy base material is typically used.

The surface roughness (Ra) of the substrate may be equal to or less than 200 nm, equal to or less than 180 nm, or equal to or less than 160 nm from the viewpoint of reducing halation due to irregularity of the substrate and improving resolution and may be equal to or greater than 10 nm, equal to or greater than 30 nm, or equal to or greater than 40 nm from the viewpoint of improving adhesion of the resist pattern. Ra may be 10 nm to 200 nm, 30 nm to 180 nm, or 40 nm to 160 nm from the viewpoint of keeping a balance between resolution and adhesion.

In a case where the photosensitive element is used, the photosensitive layer formation process is preferably performed under a reduced pressure in view of adhesion and followability. The photosensitive layer and/or the substrate may be heated at a temperature of 70° C. to 130° C. during press-bonding. Although the pressure-bonding may be performed at a pressure of about 0.1 MPa to 1.0 MPa (about 1 kgf/cm² to 10 kgf/cm²), these conditions are to be appropriately selected as needed. Note that although it is not necessary to perform preheating process of the substrate in advance if the photosensitive layer is heated to 70° C. to 130° C., it is also possible to perform the preheating process of the substrate in order to further improve adhesion and followability.

### (Exposure Process)

In the exposure process, at least a part of the photosensitive layer formed on the substrate is irradiated with active rays, and the part irradiated with the active rays is thus photocured to thereby form a latent image. At this time, although it is possible to perform the irradiation with the active rays through the support in a case where the support is present on the photosensitive layer, and the support transmits the active rays therethrough, the support is removed, and the photosensitive layer is then irradiated with the active rays in a case where the support blocks the rays.

Examples of an exposure method includes a method of performing imagewise irradiation with active rays through a negative or positive mask pattern called an artwork (mask exposure method). Further, a method of performing imagewise irradiation with active rays by a projection exposure method may be adopted. Alternatively, a method of performing imagewise irradiation with active rays by a direct drawing exposure method such as a laser direct imaging (LDI) exposure method or a digital light processing (DLP) exposure method may be adopted.

As a light source for the active rays, a known light source can be used, and examples of the light source to be used include light sources that effectively emit ultraviolet rays or visible light such as a carbon arc lamp, a mercury vapor arc lamp, a high-pressure mercury-vapor lamp, a xenon lamp, a gas laser such as an argon laser, a solid laser such as a YAG laser, and a semiconductor laser.

### (Developing Process)

In the developing process, at least a part of the unphotocured portion (other than the photocured portion) of the photosensitive layer is removed from the substrate to thereby form a resist pattern on the substrate. In the case where the support is present on the photosensitive layer, the support is removed, and the region (which may also be referred to as an unexposed part) other than the photocured portion is then removed (developed). As a developing method, there are wet development and dry development, and the wet development has widely been used.

In the case of performing wet development, the development is performed by a known developing method using a developer corresponding to the photosensitive resin composition. Examples of the developing method include a dip method, a paddle method, a spraying method, and methods using brushing, scrubbing, swinging immersion, and the like. From the viewpoint of improving resolution, a high-pressure spraying method may be used as the developing method. Two or more kinds from among these methods may be combined to perform the development.

The constitution of the developer is appropriately selected in accordance with the constitution of the above-described photosensitive resin composition. Examples of the developer include an alkaline aqueous solution and an organic solvent developer.

From the standpoint of safety, stability, and satisfactory operability, an alkaline aqueous solution may be used as the developer. Examples of a base in the alkaline aqueous solution to be used include: alkali hydroxides such as lithium, sodium, and potassium hydroxides; alkali carbonates such as lithium, sodium, potassium, and ammonium carbonates or bicarbonates; alkali metal phosphates such as potassium phosphate and sodium phosphate; alkali metal pyrophosphates such as sodium pyrophosphate and potassium pyrophosphate; borax, sodium metasilicate, tetramethylammonium hydroxide, ethanolamine, ethylenediamine, diethylenetriamine, 2-amino-2-hydroxymethyl-1,3-propanediol, 1,3-diaminopropanol-2, and morpholine.

As the alkaline aqueous solution to be used for the development, a dilute solution of 0.1% by mass to 5% by mass sodium carbonate, a dilute solution of 0.1% by mass to 5% by mass potassium carbonate, a dilute solution of 0.1% by mass to 5% by mass sodium hydroxide, a dilute solution of 0.1% by mass to 5% by mass sodium tetraborate, or the like can be used. pH of the alkaline aqueous solution may be in the range of 9 to 11, and the temperature thereof can be adjusted in accordance with the alkaline developability of the photosensitive layer. For example, a surfactant, a defoaming agent, a small amount of an organic solvent for promoting the development, and the like may be mixed into the alkaline aqueous solution.

Examples of the organic solvent to be used in the alkaline aqueous solution include acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether.

Examples of the organic solvent to be used in the organic solvent developer include 1,1,1-trichloroethane, N-methyl-2-pyrrolidone, N,N-dimethylformamide, cyclohexanone, methylisobutyl ketone, and γ-butyrolactone. To prevent flaming, water may be added within a range of 1% by mass to 20% by mass to the organic solvent to thereby obtain the organic solvent developer.

The method of forming a resist pattern in the present embodiment may include a process of further curing the resist pattern by performing heating at about 60° C. to 250° C. or exposure at about 0.2 J/cm² to 10 J/cm² as needed after the uncured part is removed in the developing process.

### [Method of Manufacturing Wiring Substrate]

A method of manufacturing a wiring substrate of the present embodiment includes a process of performing etching process or plating process on a substrate with a resist pattern formed thereon by the above-described method of forming a resist pattern to thereby form a conductor pattern, and the method may also be configured to include other processes such as the resist pattern removal process as needed.

In the etching process, a conductor layer provided on the substrate is etched and removed using the resist pattern formed on the substrate as a mask to thereby form a conductor pattern. A method of the etching process is appropriately selected in accordance with a conductor layers to be removed. Examples of an etching solution include a copper(II) chloride solution, an iron(II) chloride solution, an alkali etching solution, and hydrogen peroxide-based etching solutions.

In the plating process, plating process is performed on the conductor layer provided on the substrate using the resist pattern formed on the substrate as a mask. The conductor pattern may be formed by removing the resist by removing a resist pattern, which will be described later, after the plating process and further etching the conductor layer covered with the resist. A method of the plating process may be either electrolytic plating process or electroless plating process and may be electroless plating process.

After the etching process or the plating process, the resist pattern on the substrate is removed. The resist pattern can be peeled off with, for example, an inorganic alkali stripper or an organic alkali stripper. Examples of the inorganic alkali stripper to be used include an aqueous solution of 1% by mass to 10% by mass of sodium hydroxide and an aqueous solution of 1% by mass to 10% by mass of potassium hydroxide. Examples of the organic alkali stripper to be used include amine-based strippers such as ethanolamine, ethylenediamine, and diethylenetriamine and an aqueous solution of tetramethylammonium hydroxide. From the viewpoint of releasability of the thick film resist pattern, an organic alkali stripper may be used.

Examples of a method of removing the resist pattern include a dipping method and a spraying method, and these methods may be used alone or together.

In the case where the resist pattern is removed after the plating process is performed, it is possible to manufacture a desired print wiring board by further performing etching process to etch the conductor layer covered with the resist to form a conductor pattern. A method of the etching process at this time is appropriately selected in accordance with the conductor layer to be removed. For example, the above-described etching solution can be applied.

The method of manufacturing the wiring substrate according to the present embodiment can be applied not only to manufacturing of a single-layer wiring substrate but also to manufacturing of a multilayer wiring substrate and can also be applied to manufacturing of a wiring substrate including a small-diameter through-hole and the like.

### EXAMPLES

Although the present disclosure will be further specifically explained by Examples, the present disclosure is not limited to these Examples.

### [Photosensitive Resin Composition]

Photosensitive resin compositions were prepared by mixing the components shown in Table 1 in the blending amounts (parts by mass) shown in the same table. Note that the blending amounts (parts by mass) of the components other than the solvents shown in Table 1 are masses of non-volatile matters (amounts of solid content). Details of the components shown in Table 1 are as follows.

### (Component (A))

A-1: Ethylene glycol monomethyl ether/toluene solution (solid content: 47% by mass) of copolymer of methacrylic acid/methyl methacrylate/styrene/benzyl methacrylate (mass ratio: 27/5/45/23, Mw: 47000, acid value: 176.1 mgKOH/g, Tg: 107° C.) (Component (B))
b1-1: Dicyclopentanyl acrylate (manufactured by Resonac Corporation, trade name: “FA-513AS”)
b1-2: Dicyclopentanyl methacrylate (manufactured by Resonac Corporation, trade name: “FA-513M”)
b1-3: Isobornyl acrylate (manufactured by Osaka Organic Chemical Industry Ltd.)
b2-1: 70, solution of propylene glycol monomethyl ether of 2,2-bis(4-(methacryloxyethoxy)phenyl)propane (average of 10 mol adduct of ethylene oxide) (manufactured by Resonac Corporation, trade name: “FA-321M”)
b2-2: Tricyclodecanedimethanol diacrylate (manufactured by Shin-Nakamura Chemical Co., Ltd., trade name: “A-DCP”)
b2-3: Ethoxylated bisphenol A diacrylate (manufactured by Shin-Nakamura Chemical Co., Ltd., trade name: “A-BPE-10”) (Component (C))
BCIM: 2,2′-bis(o-chlorophenyl)-4,4′,5,5′-tetraphenyl-1,2′-biimidazole (manufactured by Hampford Research Inc.) (Component (D))
DBA: 9,10-dibutoxyanthracene (manufactured by Kawasaki Kasei Chemicals Ltd.)

### (Other Components)

Hydrogen donor: Leuco crystal violet (manufactured by Yamada Chemical Co., Ltd.)
Dye: Malachite green (manufactured by Osaka Organic Chemical Industry Ltd.)

### [Photosensitive Element]

As a support, a polyethylene terephthalate film (manufactured by Toray Industries, Inc., trade name: “FB-40”) having a thickness of 16 μm was prepared. The photosensitive resin composition was applied to the support and was then successively dried with hot air convection driers at 80° C. and 120° C. to form a photosensitive layer having a thickness of 40 μm after the drying. A polyethylene film (manufactured by Tamapoly Co., Ltd., trade name: “NF-15”) was attached as a protective layer to the photosensitive layer to obtain a photosensitive element in which the support, the photosensitive layer, and the protective layer were stacked in order.

### [Laminate L1]

A copper-clad laminate (manufactured by Resonac Corporation, trade name: “MCL-E-67”) including a glass epoxy material and copper foils (thickness: 16 μm) disposed on both sides thereof was pickled, washed with water, and then dried with an air flow. Next, the copper-clad laminate was heated to 80° C., and the photosensitive element was then laminated on the copper-clad laminate in such a manner that the photosensitive layer was in contact with the copper surface while the protective layer was peeled off, thereby obtaining a laminate L1 including the copper-clad laminate, the photosensitive layer, and the support in order. The lamination was carried out using a heat roll at 110° C. at a pressure-bonding pressure of 0.4 MPa at a roll rate of 1.0 m/min.

### [Laminate L2]

The above-described photosensitive element was laminated on a Cu-sputtered PET film (manufactured by Geomatec Co., Ltd., plate thickness: 125 μm) in such a manner that the photosensitive layer was in contact with the copper surface while the protective layer was peeled off, thereby obtaining a laminate L2 including the Cu-sputtered PET film, the photosensitive layer, and the support in order. The lamination was carried out using a heat roll at 110° C. at a pressure-bonding pressure of 0.4 MPa at a roll rate of 1.0 m/min.

### [Evaluation]

The following evaluation was carried out using the laminates L1 and L2. The results are shown in Table 2.

### (Minimum Development Time)

After the laminate L1 was cut into a square (5 cm×5 cm), the support was peeled off to obtain a test piece. Next, an unexposed photosensitive layer in the test piece was spray-developed at a pressure of 0.18 MPa by using a 1% by mass of aqueous solution of sodium carbonate at 30° C., and a time in which the fact that the unexposed photosensitive layer of equal to or greater than 1 mm had been removed was able to be visually confirmed was regarded as a minimum developing time (MD). As a nozzle in the spray-development, a full cone-type nozzle was used. The distance between the test piece and the nozzle tip was 6 cm, and the test piece and the nozzle were disposed such that the centers thereof coincided with each other. The shorter minimum developing time (unit: second) means better developing property.

### (Sensitivity)

After a Hitachi 41-step tablet was placed on the support of the laminate L1, the photosensitive layer was exposed through the support using a direct drawing exposure machine (manufactured by Orc Manufacturing CO. Ltd., trade name: “FDi-Ms”) using a blue-violet laser diode having a wavelength of 405 nm as a light source with an exposure amount (irradiation energy amount) such that the number of remaining steps of the Hitachi 41-step tablet was 15. Sensitivity (photosensitivity) was evaluated on the basis of the exposure amount (unit: mJ/cm²) at this time. The lower exposure amount means higher sensitivity.

### (Adhesion)

The photosensitive layer of the laminate L1 was exposed by the direct drawing exposure machine (FDi-Ms) in an exposure amount such that the number of remaining steps of the Hitachi 41-step tablet was 15 using a drawing pattern with a line width (L)/space width (S) of x/3x (x=3 to 30, unit: μm, interval: 1 μm).

### (Resolution)

The photosensitive layer of the laminate L1 was exposed by the direct drawing exposure machine (FDi-Ms) in an exposure amount such that the number of remaining steps of the Hitachi 41-step tablet was 15 using a drawing pattern with a line width (L)/space width (S) of x/3x (x=3 to 30, unit: μm, interval: 1 μm).

After the exposure, the support was peeled off from the laminate L1, the photosensitive layer was exposed, and a 1% by mass of aqueous solution of sodium carbonate was sprayed thereto at 30° C. for a period of time that was twice as long as the minimum developing time to thereby remove an unexposed portion. After the development, a space part (unexposed portion) was removed without any residue, resolution was evaluated by the minimum value (unit: μm) of space widths in a resist pattern in which the line part (exposed portion) was formed without meandering and chipping, and adhesion was evaluated by the minimum value (unit: μm) of the line widths in the resist pattern. The smaller numerical values mean better resolution and adhesion.

### (Round-Hole Resolution)

Using a via pattern (via hole pattern) with a round hole opening portion diameter/pitch between round hole centers of x/1.5x (x=10 to 50, unit: μm, interval: 1 μm), the photosensitive layer of the laminate L2 was exposed by the direct drawing exposure machine (FDi-Ms) in an exposure amount such that the number of remaining steps of the Hitachi 41-step tablet was 15.

After the exposure, the support was peeled off from the laminate L2, the photosensitive layer was exposed, and 1% by mass of aqueous solution of sodium carbonate was sprayed thereto at 30° C. for a period of time that was twice as long as the minimum developing time to thereby remove an unexposed portion. The formed via pattern (via hole pattern) was observed with an optical microscope, and round-hole resolution was evaluated on the basis of the value of the smallest via pattern diameter from among the via patterns aligned in a grid pattern that have been clearly and completely removed (opened). The smaller numerical value means better round-hole resolution.

### (Releasability)

A glass chromium-type phototool (having a planar pattern of 45 mm×60 mm) was used as a peeling-off test evaluation negative on the support of the laminate L1, and the photosensitive layer was exposed through the support using the direct drawing exposure machine (FDi-Ms) in the exposure amount such that the number of remaining steps of the Hitachi 41-step tablet was 15.

After the exposure, the support was peeled off from the laminate L1, the photosensitive layer was exposed, and 1 by mass of aqueous solution of sodium carbonate was sprayed thereto at 30° C. for a period of time that was twice as long as the minimum developing time to thereby remove an unexposed portion and obtain a substrate with a cured film formed thereon. This substrate was left to stand at a room temperature for 3 hours and was then immersed in an amine-based stripper (an aqueous solution of 6% by volume R−100S+2% by volume R−101, manufactured by Mitsubishi Gas Chemical Company, Inc.) which was heated to 50° C., and the solution was stirred at a speed of 400 rpm. The time until the cured film was completely removed from the substrate after the start of the stirring was regarded as a peeling-off time (unit: second). The shorter stripping time means better releasability.

TABLE 1

| | | Example | | | Comparative example | | | | | | | | |
|---|---|---|---|---|---|---|---|---|---|---|---|---|---|
| | | 1 | 2 | 3 | 1 | 2 | 3 | 4 | 5 | 6 | 7 | 8 | 9 |
| (A) | A-1 | 57 | 57 | 57 | 57 | 57 | 57 | 57 | 57 | 57 | 57 | 57 | 57 |
| (B) | b1-1 | 3 | — | — | — | 8 | — | — | — | — | — | — | — |
| | b1-2 | — | 3 | — | — | — | 8 | — | — | — | — | — | — |
| | b1-3 | — | — | 3 | — | — | — | 8 | — | — | — | — | — |
| | b2-1 | 40 | 40 | 40 | 43 | 35 | 35 | 35 | 40.8 | 38.6 | 35 | 28 | — |
| | b2-2 | — | — | — | — | — | — | — | 2.2 | 4.4 | 8 | — | — |
| | b2-3 | — | — | — | — | — | — | — | — | — | — | 15 | 43 |
| (C) | B-CIM | 5 | 5 | 5 | 5 | 5 | 5 | 5 | 5 | 5 | 5 | 5 | 5 |
| (D) | DBA | 0.65 | 0.65 | 0.65 | 0.65 | 0.65 | 0.65 | 0.65 | 0.65 | 0.65 | 0.65 | 0.65 | 0.65 |
| Hydrogen donor | | 0.5 | 0.5 | 0.5 | 0.5 | 0.5 | 0.5 | 0.5 | 0.5 | 0.5 | 0.5 | 0.5 | 0.5 |
| Dye | | 0.01 | 0.01 | 0.01 | 0.01 | 0.01 | 0.01 | 0.01 | 0.01 | 0.01 | 0.01 | 0.01 | 0.01 |
| Solvent | Acetone | 5 | 5 | 5 | 5 | 5 | 5 | 5 | 5 | 5 | 5 | 5 | 5 |
| | Toluene | 12 | 12 | 12 | 12 | 12 | 12 | 12 | 12 | 12 | 12 | 12 | 12 |
| | Methanol | 5 | 5 | 5 | 5 | 5 | 5 | 5 | 5 | 5 | 5 | 5 | 5 |

TABLE 2

| | Example | | | Comparative example | | | | | | | | |
|---|---|---|---|---|---|---|---|---|---|---|---|---|
| | 1 | 2 | 3 | 1 | 2 | 3 | 4 | 5 | 6 | 7 | 8 | 9 |
| Sensitivity (mJ/cm²) | 53 | 50 | 51 | 51 | 56 | 48 | 51 | 55 | 59 | 66 | 56 | 71 |
| Minimum developing time | 40 | 40 | 40 | 37 | 43 | 43 | 43 | 38 | 39 | 41 | 37 | 32 |
| (second) | | | | | | | | | | | | |
| Adhesion (μm) | 16 | 16 | 14 | 16 | 25 | 25 | 20 | 20 | 18 | 14 | 20 | 25 |
| Round-hole resolution | 6 | 6 | 6 | 6 | 6 | 6 | 6 | 6 | 6 | 6 | 7 | 10 |
| (μmΦ) | | | | | | | | | | | | |
| Peeling-off time (second) | 111 | 111 | 96 | 116 | 84 | 87 | 84 | 122 | 115 | 101 | 92 | 70 |
| Peeling-off piece size (mm) | 3 | 3 | 3 | 3 | 3 | 3 | 3 | 3 | 5 | 3 | 5 | 3 |

### REFERENCE SIGNS LIST

1 Photosensitive element
2 Support
3 Photosensitive layer
4 Protective layer

1. A photosensitive resin composition comprising: a binder polymer; a photopolymerizable compound; a photopolymerization initiator; and a sensitizer, wherein
the photopolymerizable compound includes monofunctional (meth)acrylate having a bicyclo skeleton, and
a content of the monofunctional (meth)acrylate having a bicyclo skeleton is less than 5.0 parts by mass with respect to 100 parts by mass of a total amount of the binder polymer and the photopolymerizable compound.

2. The photosensitive resin composition according to claim 1, wherein the content of the monofunctional (meth)acrylate having a bicyclo skeleton is 1.0 parts by mass to 4.5 parts by mass with respect to 100 parts by mass of the total amount of the binder polymer and the photopolymerizable compound.

3. The photosensitive resin composition according to claim 1, wherein the photopolymerizable compound further includes bisphenol A type (meth)acrylate.

4. The photosensitive resin composition according to claim 1, wherein the sensitizer includes an anthracene compound.

5. A photosensitive element comprising: a support; and a photosensitive layer formed on the support using the photosensitive resin composition according to claim 1.

6. The photosensitive element according to claim 5, wherein a thickness of the photosensitive layer is equal to or greater than 30 μm.

7. A method of forming a resist pattern, comprising:
forming a photosensitive layer on a substrate using the photosensitive element according to claim 6;
irradiating at least a part of the photosensitive layer with active rays to form a photocured portion; and
removing an unphotocured portion of the photosensitive layer from the substrate to form a resist pattern.

8. A method of manufacturing a wiring substrate, comprising:
performing etching process or plating process on a substrate with a resist pattern formed thereon by the method of forming a resist pattern according to claim 7 to form a conductor pattern.

9. The method of manufacturing a wiring substrate according to claim 8, further comprising: removing the resist pattern using an organic alkali stripper after the etching process or the plating process.
